(19) United States
(12) Patent Application Publication
(10) Pub. No.: US 2004/0172886 A1
(43) Pub. Date: Sep. 9, 2004

(54) CMP composition based on cupric oxidizing compounds

(76) Inventor: John Grunwald, Tel Aviv (IL)

Correspondence Address: John L. Cordani, Carmody & Torrance LLP, 50 Leavenworth Street, P.O. Box 1110, Waterbury, CT, 06721-1110, US

(21) Appl. No.: 10/425,364

(22) Filed: Apr. 29, 2003

(30) Foreign Application Priority Data
Mar. 6, 2003 (IL) 154783

(51) Int. Cl. B44C 1/22; B24D 3/02

(52) U.S. Cl. 51/307; 216/89; 438/692; 438/693

(57) ABSTRACT

A composition useful in planarizing metal or semi-conductor surfaces, especially copper surfaces, is disclosed. The composition disclosed comprises cupric salts as an oxidizing agent and also preferably comprises complexing agents such as ethylene diamine tetraocetic acid. The polishing rate can be varied by adjusting the pH and/or temperature of the composition.

### FIELD OF INVENTION

The invention relates to wafer planarizing compositions, known in the industry as CMP, for chemical mechanical polishing.

### BACKGROUND OF THE INVENTION

With the growing demand for ever greater miniaturazation of ULSI devices, planarization via CMP becomes an increasingly critical aspect in the fabrication sequence of semiconductor devices. The challenge stems from the multitude and differing nature of materials used in the various layers, the demanding geometries and aspect ratios of the structures, the ever present quest for improved yields via reduction of defects, etc.

Patent applications WO 02/083804 to Costas, US 2002/0177316 A1 to Miller and WO 01/44396 A1 to Sachan, are referenced herewith, as indicative of the methods and compositions of typical CMPs of the prior art. They reflect the differing natures of CMP compositions, dictated by the tasks/problems they need to address, such as nature of the layers, selectivity, surface roughness and throughput, to name only very few.

CMP slurries can be somewhat simplistically described as consisting of abrasive particulate matter suspended in aq., desirably stable compositions. Such susspensions can contain a host of additives, pH adjusters, leveling agents, surfactants, emulsifiers where needed, and the like. In CMP, the slurry is usually dispensed on a rotating pad in contact with a rotating wafer. Planarization thus involves a combination of abrasion and chemical reaction at the wafer/slurry interface.

A significant, and generally central component of various metal-polishing slurries, is an oxidizing agent, with hydrogen peroxide and inorganic nitrates perhaps prevalent. Generally, the oxidizing agent is tailored to suit a given metal to be polished, with copper believed to be the most challenging. Indeed, copper is becoming the metal of choice for interconnect applications, due to its superior electrical conductivity.

While hydrogen peroxide is an attractive oxidizing agent because of reasonable cost, it is not without some serious drawbacks, namely poor stability especially in presence of transition metals, known to catalyze decomposition. Another shortcoming of H₂O₂ is its less than ideal selectivity. Further, the reaction of peroxides during dissolution of copper, is highly exothermic, making it problematic to maintain temperature stability at the copper/slurry interface, where polishing takes place.

U.S. Pat. No. 6,448,182 to Hall addresses the stability issue through incorporation of stabilizers that are said to reduce, but will not eliminate, decomposition.

The prior art proposes the use of corrosion inhibitors, typically benzotriazoles, as a way to minimize copper oxidation and improve selectivity. Indeed, benzotriazole is extensively used in the prior art in connection with a host of processes involving copper, due to its somewhat specific protective, film-forming properties with copper metal, thus serving as a corrosion/oxidation inhibitor for Cu.

Some CMP compositions of the prior art are also based on inorganic nitrates as oxydizing agents. Inorganic nitrates, however, tend to be too aggressive and corrosive, and will not generally favor selectivity, especially for copper.

Further, oxidizing agents of the prior art are somewhat “pH specific”, often requiring operation in a rather restricted pH range, resulting in a somewhat narrow operating window. Thus, the prior art appears to necessitate different oxidizers depending on the metal to be polished, often necessitating a delicate balancing act when formulating polishing slurries, in processes where more than one metal is exposed to the slurry composition.

Oxidizing compositions of the prior art polishing compositions tend to be costly, and can be less that environmantally “friendly”. Also, they are not easily recyclable, a most desired feature wherever applicable.

### SUMMARY OF THE INVENTION

The present invention discloses the use of inorganic cupric copper (Cu⁺⁺) salts, as the principal, often sole oxidizing chemical, of CMP compositions. Unlike H₂O₂, cupric copper is not a multipurpose oxidizing agent, and is somewhat specific in its interaction with copper and other metals. Its interaction with copper metal can be schematically explained by the following chemical equation:

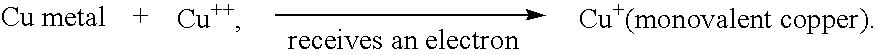

The monovalent copper ion is reoxidized with O₂ to yield cupric copper, and so on.

Thus, according to a first asect, the present invention provides a chemical metal polishing (CMP) composition comprising inorganic cupric salt (Cu⁺⁺) or mixture of such salts as an oxidizer. In a specific embodiment the composition is intended for polishing copper metal.

According to a second aspect, the present invention provides a method for polishing a substrate including at least one conducting or semiconducting layer, the method comprising applying the composition described above to the substrate; and removing at least a portion of the conducting or semiconducting layer from the substrate by bringing a pad into contact with the substrate and moving the pad in relation to the substrate.

### BRIEF DESCRIPTION OF THE INVENTION

Cupric salts for use in CMP compositions offer the following benefits and advantages over the prior art:

1. They are inexpensive, since being produced/generated as by-products in the manufacture of Printed Wiring Boards (PWB). They can be recycled for re-use.

2. They interact with copper and metals in general, in both acid and alkaline environments, thus offering a wide selection of compositions, unrestricted by pH.

3. Unlike H₂O₂, they are safely stored, without requiring spacial precautions.

CMP compositions of the invention can be embodied with acidic cupric salts. The desired rate of copper polishing can be adjusted by varying pH, and temperature of the slurry.

When choosing alkaline embodiments, CMP compositions comprise complexing agents. In the case of polishing copper metal, such complexors can be selected from the group of salts of hydroxy acids such as tartaric, citric, glycolic, etc., amines, ammonia, EDTA, Quadrol are also possible choices for metal complexor.

As to concentrations, they can range from 1 g/l to saturation of cupric salts, when present as sole oxidizer of CMP, but can be 0.1-1 g/l when comprising other oxydizing agents.

In practicing the invention, one can be assisted by copper etching processes used in the fabrication of PWBs, exemplified by U.S. Pat. No. 4,132,585 to Oxford and U.S. Pat. No. 5,560,838 to Allies.

1. A chemical metal polishing (CMP) composition comprising inorganic cupric salt (Cu⁺⁺) or mixture of such salts as an oxidizer.

2. The composition of claim 1 for polishing copper metal.

3. The composition of claim 1 or 2, further comprising a complexing agents.

4. The composition of claim 3 for polishing copper metal, wherein said complexing agent is selected from the group of salts of hydroxy acids, amines, ammonia, EDTA and Quadrol.

5. The composition of claim 4, wherein said salts of hydroxy acids are selected from salts of tartaric, citric and glycolic acid.

6. The composition of claim 1 wherein the concentration of the cupric salt is in the range of about 1 g/l to about 20 g/l or higher when used as sole oxidizing agent of the composition.

7. The composition of claim 1 wherein the concentration of the cupric salt is in the range of between about 0.1 to about 1 g/l or less when in the presence of additional oxidizing agents.

8. A method for polishing a substrate including at least one conducting or semiconducting layer, the method comprising applying the composition of anyone of claims 1 to 7 to the substrate; and removing at least a portion of the conducting or semiconducting layer from the substrate by bringing a pad into contact with the substrate and moving the pad in relation to the substrate.
